(19) United States
(12) Patent Application Publication
(10) Pub. No.: US 2011/0279765 A1
(43) Pub. Date: Nov. 17, 2011

(54) DISPLAY DEVICE

(76) Inventor: Eiji OOHIRA, Mobara (JP)

(21) Appl. No.: 13/106,916

(22) Filed: May 13, 2011

(30) Foreign Application Priority Data
May 14, 2010 (JP) 2010-111619

(51) Int. Cl. G02F 1/1345; H05K 1/02

(52) U.S. Cl. 349/150; 174/254

(57) ABSTRACT

Provided is a display device including a flexible substrate having a shield electrode formed thereon, which enables reduction of a region in which components are mounted compared with that in a conventional case. The display device includes: a display panel; and a flexible substrate connected to the display panel, the flexible substrate having a plurality of electronic components mounted thereon, in which: the flexible substrate has a shield electrode on a surface thereof that is opposite to a surface thereof on which the plurality of electronic components are mounted in a region which corresponds to a region in which the plurality of electronic components are mounted; the shield electrode is supplied with a first reference voltage from outside; and at least one of the plurality of electronic components is supplied with the first reference voltage via the shield electrode.

### CROSS-REFERENCE TO RELATED APPLICATION

The present application claims priority from Japanese application JP 2010-111619 filed on May 14, 2010, the content of which is hereby incorporated by reference into this application.

### BACKGROUND OF THE INVENTION

1. Field of the Invention

The present invention relates to a display device, and more particularly, to a technology for reducing electro magnetic interference (EMI) of a display device.

2. Description of the Related Art

In a cellular telephone, it is often the case that reduction of electro magnetic interference (EMI) generated in a liquid crystal display module used as a display portion is required from the beginning of development in order to improve receiving sensitivity of one-segment broadcasting or the like. More specifically, specifications in which a shield electrode is formed on one surface of a flexible substrate (on a surface having no component mounted thereon and immediately below an electronic component) are prescribed.

JP 2007-103560 A is known as an example in which a shield electrode is added to a surface of a double-sided wiring (two-layer wiring) flexible substrate.

JP 2007-103560 A describes that a plurality of thin film capacitors having arbitrary capacitances are formed on a flexible substrate by a shield electrode.

FIG. 1 is an exploded perspective view schematically illustrating a structure of a conventional liquid crystal display device for a cellular telephone.

As illustrated in FIG. 1, the conventional liquid crystal display device includes a liquid crystal display panel (LCD) and a backlight unit (B/L) for illuminating the liquid crystal display panel (LCD). The backlight unit (B/L) includes alight guide plate 6 which is substantially in the shape of a rectangle similar to the shape of the liquid crystal display panel (LCD) seen in plan view, white light-emitting diodes (light sources) 8 disposed on one side (light incident side) of the light guide plate 6, a reflection sheet 7 disposed on a lower surface (surface which is opposite to the liquid crystal display panel (LCD) side) side of the light guide plate 6, an optical sheet group 5 disposed on an upper surface (surface which is on the liquid crystal display panel side) of the light guide plate 6, and a resin molded frame 10. The optical sheet group 5 includes, for example, a lower diffusion sheet, two lens sheets, and an upper diffusion sheet.

The liquid crystal display panel (LCD) includes a pair of glass substrates (2a and 2b), an upper polarizing plate 1 adhered to an upper surface (display surface) of the glass substrate 2a, and a lower polarizing plate 3 adhered to a lower surface (surface on the backlight unit side) of the glass substrate 2b.

The glass substrate 2b has a semiconductor chip 11 mounted thereon which forms a driver and the like. Note that, a flexible substrate for supplying a control signal and the like to the semiconductor chip 11 is mounted on the glass substrate 2b, but the flexible substrate is not illustrated in FIG. 1.

FIG. 2 is a plan view of the conventional liquid crystal display device illustrated in FIG. 1 for a cellular telephone, and FIG. 3 is a bottom view of the conventional liquid crystal display device illustrated in FIG. 1 for a cellular telephone.

FIG. 2 illustrates a state in which a flexible substrate (FPC) is electrically and mechanically mounted on a terminal portion formed at an end of a portion of the glass substrate 2b of the liquid crystal display panel (LCD) on which the glass substrate 2a is not overlaid. Note that, in FIG. 2, FPC-T is a terminal portion which is an interface with the outside, and, in FIG. 3, FPC-LD is a flexible substrate for mounting LEDs thereon, on which the light-emitting diodes 8 are mounted.

As illustrated in FIG. 2, an electronic component group 20 including a resistance element and a capacitor which assists operation of the semiconductor chip 11 and which functions as a bypass capacitor for a power supply voltage supplied from the outside, respectively, is mounted on the flexible substrate (FPC). The number of the electronic components varies depending on the liquid crystal display device, but is ten or more and less than sixty.

FIG. 3 illustrates a state in which a shield electrode 30 for reducing electro magnetic interference (EMI) is formed on the flexible substrate (FPC). The shield electrode 30 is provided on a surface of the flexible substrate (FPC) which is opposite to a surface on which the electronic component group 20 is mounted so as to cover a region in which the electronic component group 20 illustrated in FIG. 2 is mounted, and a ground voltage (GND) is supplied to the shield electrode 30.

### SUMMARY OF THE INVENTION

For example, in the conventional liquid crystal display device illustrated in FIGS. 1 to 3, when the ground voltage (GND) is supplied to an electronic component mounted on the flexible substrate (FPC), it is necessary to route, in a manner avoiding other signal wiring patterns, a GND wiring from a ground voltage terminal (hereinafter, referred to as GND terminal) of the flexible substrate (FPC) to a terminal of the electronic component mounted on the flexible substrate (FPC) to which the ground voltage is supplied.

Therefore, there is a problem that, in particular, as the number of the components to which the ground voltage is supplied becomes larger, the region in which the components are mounted becomes larger.

The present invention is made to solve the problem of the conventional liquid crystal display device described above, and an object of the present invention is to provide a technology which enables, in a display device including a flexible substrate having a shield electrode formed thereon, reduction of a region in which components are mounted compared with that in a conventional case.

The above and other objects and novel features of the present invention are made clear by the description of the present specification in conjunction with the accompanying drawings.

Among aspects of the present invention disclosed herein, representative ones are briefly described below. (1) A display device according to an aspect of the present invention includes: a display panel; and a flexible substrate connected to the display panel, the flexible substrate having a plurality of electronic components mounted thereon, in which: the flexible substrate has a shield electrode on a surface thereof that is opposite to a surface thereof on which the plurality of electronic components are mounted in a region which corresponds to a region in which the plurality of electronic components are mounted; the shield electrode is supplied with a first reference voltage from outside; and at least one of the plurality of electronic components is supplied with the first reference voltage via the shield electrode. (2) In the display device as described in the item (1), 20% or more of the plurality of electronic components is supplied with the first reference voltage via the shield electrode. (3) In the display device as described in the item (1) or (2), the flexible substrate includes: a base film; a plurality of first wiring layers formed on a surface of the base film, which is on the shield electrode side; an insulating layer formed on the plurality of first wiring layers; and a plurality of second wiring layers formed on a surface of the base film, which is on the plurality of electronic components side, and the shield electrode is formed on the insulating layer. (4) In the display device as described in the item (3), the shield electrode includes, on a surface thereof, a coating layer including an insulating layer.

(5) In the display device as described in the item (3) or (4), the shield electrode is connected via a through hole formed in the insulating layer to a first wiring layer to which the first reference voltage is supplied of the plurality of first wiring layers. (6) In the display device as described in any one of the items (3) to (5), the shield electrode is connected via a through hole formed in the insulating layer and a through hole formed in the base film to a second wiring layer of the plurality of second wiring layers which supplies the first reference voltage to the at least one of the plurality of electronic components. (7) In the display device as described in any one of the items (1) to (6), the display device further includes a first substrate, and the flexible substrate is electrically and mechanically connected to a terminal portion formed at an end of an arbitrary side of the first substrate. (8) In the display device as described in the item (7), the plurality of electronic components are formed on a front surface of the flexible substrate seen from above. (9) In the display device as described in the item (7) or (8), the display device is a liquid crystal display panel, and the liquid crystal display panel includes: the first substrate; a second substrate; and liquid crystal sandwiched between the first substrate and the second substrate. (10) A display device according to another aspect of the present invention includes: a display panel; and a flexible substrate connected to the display panel, the flexible substrate having a plurality of electronic components mounted thereon, in which: the flexible substrate has a shield electrode on a surface thereof that is opposite to a surface thereof on which the plurality of electronic components are mounted in a region which corresponds to a region in which the plurality of electronic components are mounted; the shield electrode is supplied with a first reference voltage from outside; and the flexible substrate has a first reference voltage wiring, which is supplied with the first reference voltage via the shield electrode.

Effects obtained by the representative aspects of the present invention disclosed herein are briefly described below.

According to the present invention, in a display device including a flexible substrate having a shield electrode formed thereon, a region in which components are mounted may be reduced compared with that in a conventional case.

### BRIEF DESCRIPTION OF THE DRAWINGS

In the accompanying drawings:

FIG. 1 is an exploded perspective view schematically illustrating a structure of a conventional liquid crystal display device;

FIG. 2 is a plan view of the conventional liquid crystal display device illustrated in FIG. 1 for a cellular telephone;

FIG. 3 is a bottom view of the conventional liquid crystal display device illustrated in FIG. 1 for a cellular telephone;

FIG. 4 is a sectional view illustrating an example of a flexible substrate including a shield electrode illustrated in FIGS. 2 and 3;

FIGS. 5A and 5B illustrate a function and a typical effect of the shield electrode formed on the flexible substrate;

FIG. 6 illustrates an example of signal wirings and a GND wiring of the flexible substrate seen from the shield electrode side in the conventional liquid crystal display device;

FIG. 7 is a sectional view taken along the line A-A′ of FIG. 6;

FIG. 8 illustrates an example of signal wirings and a GND wiring of a flexible substrate seen from the shield electrode side in a liquid crystal display device according to an embodiment of the present invention; and

FIG. 9 is a sectional view taken along the line B-B′ of FIG. 8.

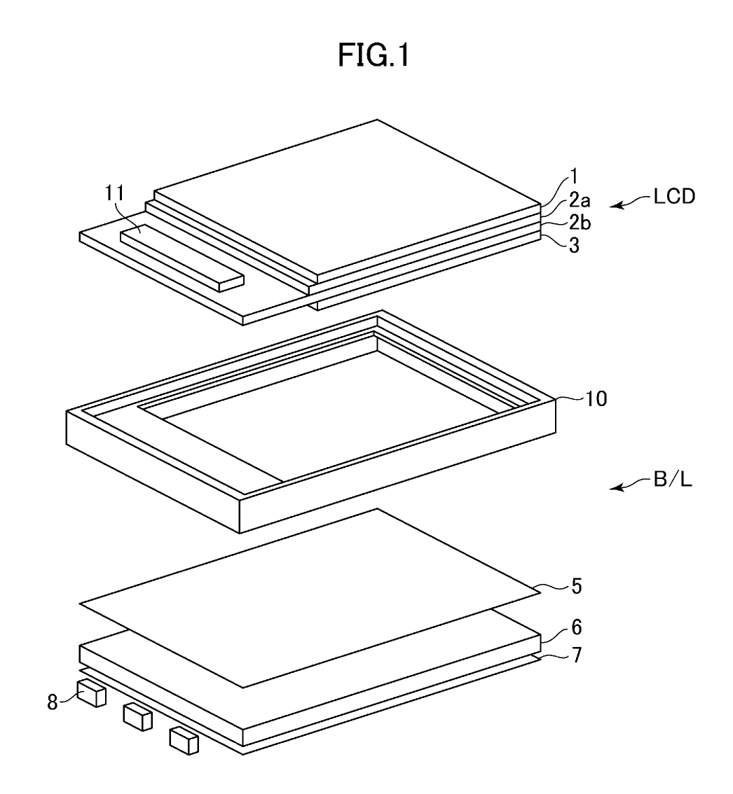

### DETAILED DESCRIPTION OF THE INVENTION

An embodiment of the present invention is described in detail in the following with reference to the attached drawings.

Note that, throughout the figures for describing the embodiment, like reference numerals are used to designate members having like functions and redundant description thereof is omitted. Further, the following embodiment by no means limits the scope of the present invention as set forth in the claims.

### [Problem of Conventional Liquid Crystal Display Device]

First, the problem of the conventional liquid crystal display device is described.

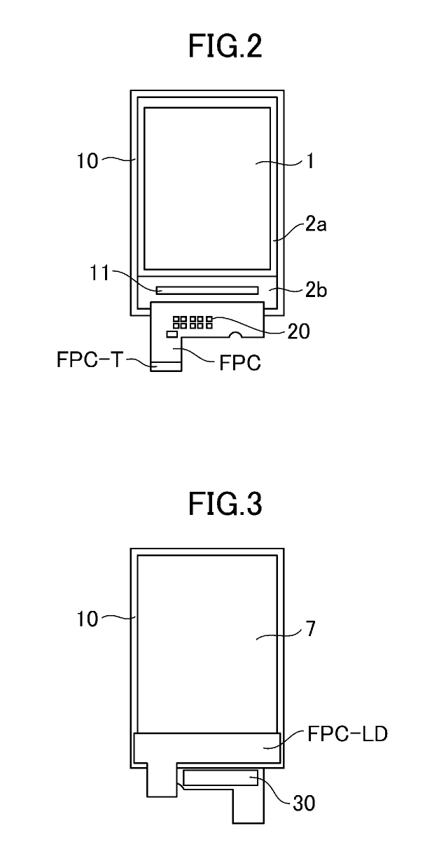

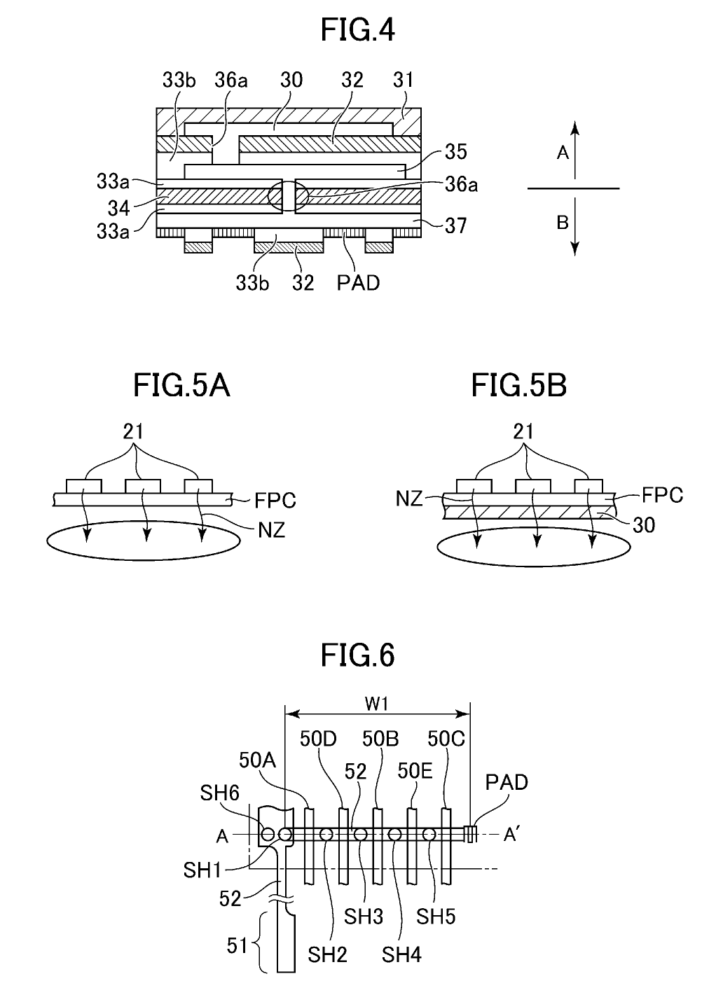

FIG. 4 is a sectional view illustrating an example of the flexible substrate FPC including the shield electrode 30 illustrated in FIGS. 2 and 3. Note that, in FIG. 4, an arrow A designates the shield electrode 30 side while an arrow B designates the side on which the electronic components are mounted.

The flexible substrate FPC has as its core a base film 34 which is a polyimide film. Patterned conductor portions 35 and 37 to be formed as wiring portions are formed on both sides of the base film 34, respectively, via an adhesive 33a.

The conductor portions 35 and 37 are connected to each other via a through hole 36a. Here, Cu is used as the conductor portions 35 and 37 and the through hole 36a. Further, polyimide films 32 are adhered to a surface of the conductor portion 35 and a surface of the conductor portion 37, respectively, via another adhesive 33b to provide electrical insulation of the surfaces.

The shield electrode 30 is formed on a surface of the polyimide film 32 which is formed on the conductor portion 35. A through hole 36b is provided in the polyimide film 32 to connect the conductor portion 35 and the shield electrode 30 to each other. Here, a material such as Ag is used as the shield electrode 30 and the through hole 36b. Further, a surface of the shield electrode 30 is usually covered with a surface coating layer 31 formed of an insulating material.

Note that, in some cases, the shield electrode 30 and the surface coating layer 31 are formed by adhering film-like materials, but graphic representation thereof is omitted here.

A bump electrode PAD for mounting the electronic component group 20 is formed on a surface of the flexible substrate FPC which is opposite to the shield electrode 30 side. With regard to the bump electrode PAD, an opening is formed in the polyimide film 32 on the surface and an Au plating layer is formed on a surface of the opening in order to provide electrical connection to the conductor portion 37.

FIGS. 5A and 5B illustrate a function and a typical effect of the shield electrode 30 formed on the flexible substrate FPC.

When the flexible substrate FPC does not include the shield electrode 30, as illustrated in FIG. 5A, radiation noise NZ is caused in all directions when an electronic component 21 of the electronic component group 20 is switched on/off, and the radiation noise NZ is caused in a region illustrated in FIG. 5A in a solid-line ellipse.

On the other hand, when the flexible substrate FPC includes the shield electrode 30, as illustrated in FIG. 5B, the radiation noise NZ caused when the electronic component 21 of the electronic component group 20 is switched on/off is blocked by the shield electrode 30, and the radiation noise NZ is not caused in a region illustrated in FIG. 5B in a solid-line ellipse.

FIG. 6 illustrates an example of signal wirings 50 and a GND wiring 52 of the flexible substrate FPC seen from the shield electrode 30 side in the conventional liquid crystal display device. In FIG. 6, wirings in solid lines exist on the shield electrode 30 side of the base film 34 while wirings in broken lines exist on a surface of the base film 34 on which the electronic components are mounted (which is opposite to the shield electrode 30 side).

Further, FIG. 6 illustrates an example of routing a wiring pattern extending from a ground voltage terminal (hereinafter, referred to as GND terminal) 51 which is an interface to the outside into the flexible substrate FPC, via a place at which the ground voltage is supplied to the shield electrode 30 (through hole SH6) and through holes SH1 to SH5, to the bump electrode PAD to which a GND terminal of the electronic component 21 is electrically and mechanically connected.

As illustrated in FIG. 6, signal wirings 50A, 50B, and 50C are aligned to the right of the GND wiring 52 which extends upward in the figure from the GND terminal 51 as obstructions in a same plane as that of the GND terminal 51.

Further, the bump electrode PAD to which the GND terminal of the electronic component 21 is electrically and mechanically connected exists on a surface opposite to the GND terminal 51 side. Further, a signal wiring 50D between the signal wiring 50A and the signal wiring 50B and a signal wiring 50E between the signal wiring 50B and the signal wiring 50C are obstructions on the surface opposite to the GND terminal 51 side.

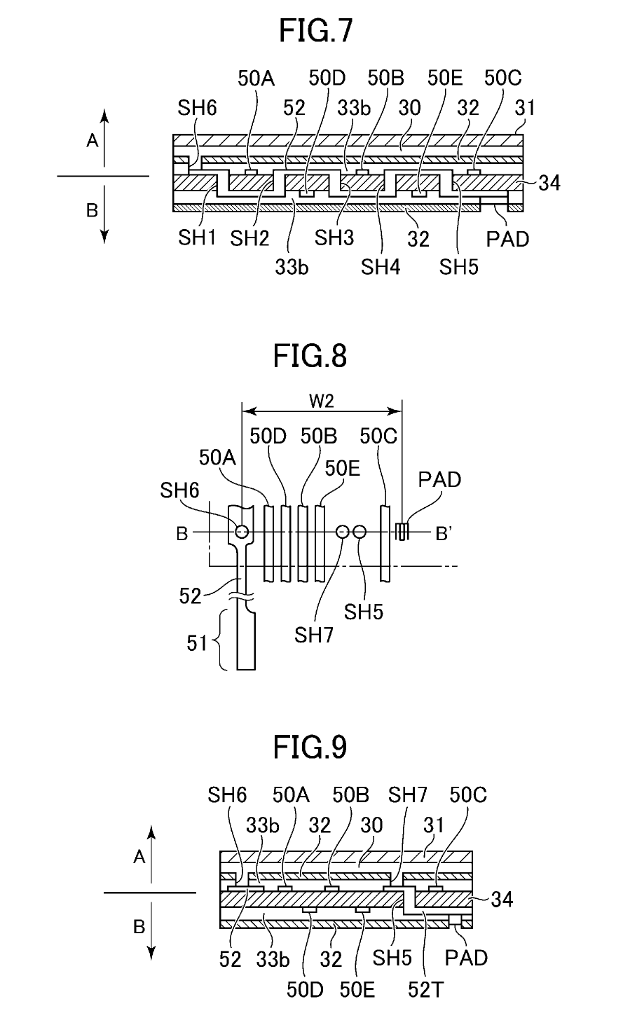

FIG. 7 is a sectional view taken along the line A-A′ of FIG. 6. Note that, the adhesive 33a is not illustrated in FIG. 7. Further, in FIG. 7, the arrow A designates the shield electrode 30 side while the arrow B designates the side on which the electronic components are mounted.

In the following, routing in the flexible substrate FPC of the conventional liquid crystal display device for connecting the GND terminal 51 and the bump electrode PAD to which the GND terminal of the electronic component 21 is electrically and mechanically connected is described with reference to FIG. 7.

First, the GND wiring 52 which extends from the GND terminal 51 is connected via the through hole SH6 to the shield electrode 30. In addition, in order to avoid the signal wiring 50A, the GND wiring 52 is routed via the through hole SH1 to the surface of the base film 34 which is opposite to the shield electrode 30 side.

Then, in order to avoid the signal wiring 50D, the GND wiring 52 is routed via the through hole SH2 back to the surface of the base film 34 on the shield electrode 30 side. Next, in order to avoid the signal wiring 50B, the GND wiring 52 is routed via the through hole SH3 to the surface of the base film 34 which is opposite to the shield electrode 30 side, and then, in order to avoid the signal wiring 50E, the GND wiring 52 is routed via the through hole SH4 back to the surface of the base film 34 on the shield electrode 30 side. Further, in order to avoid the signal wiring 50C, the GND wiring 52 is routed via the through hole SH5 to the surface of the base film 34 which is opposite to the shield electrode 30 side. In this manner, the GND wiring 52 is caused to reach the bump electrode PAD to which the GND terminal of the electronic component 21 is electrically and mechanically connected, which is the target of the connection.

The exemplary routing of the GND wiring 52 illustrated in FIG. 7 is only when the number of wiring pattern layers (conductor portions illustrated in FIG. 4) is two. When the number of the wiring pattern layers is three or four, routing via the through holes a plurality of times, for example, via the through holes SH1 to SH5 illustrated in FIG. 7, is not necessary. However, in a flexible substrate FPC of a liquid crystal display device for a cellular telephone, the number of the wiring pattern layers is limited to two from the viewpoint of cost and under the constraint that the cellular telephone is folded in use.

When the number of the wiring pattern layers is limited to two, using through holes many times is inevitable. The amount of current which instantaneously flows through the GND wiring 52 is large, and thus, compared with, for example, ordinary signal wirings such as the signal wirings 50A to 50E illustrated in FIG. 7, it is necessary to make larger the wiring width to about 0.2 mm to 0.3 mm.

Therefore, there is a problem that the width of the region in which the components are mounted of the flexible substrate FPC (W1 in FIG. 6) becomes large, and thus, the region in which the components are mounted of the flexible substrate FPC and the flexible substrate FPC become large in size.

As described above, in the conventional liquid crystal display device, downsizing of the flexible substrate FPC and of the region in which the components are mounted may not be materialized.

### Embodiment

According to the present invention, in the flexible substrate

FPC including the shield electrode 30, the shield electrode 30 is used as means for connection from the GND terminal 51 to the bump electrode PAD to which the GND terminal of the electronic component 21 is electrically and mechanically connected.

FIG. 8 illustrates an example of the signal wirings 50 and the GND wiring 52 of the flexible substrate FPC seen from the shield electrode 30 side in a liquid crystal display device according to an embodiment of the present invention. In FIG. 8, wirings in solid lines exist on the shield electrode 30 side of the base film 34 while wirings in broken lines exist on the surface of the base film 34 on which the electronic components are mounted (which is opposite to the shield electrode 30 side). Further, FIG. 9 is a sectional view taken along the line B-B′ of FIG. 8. Note that, the adhesive 33a is not illustrated in FIG. 9. Further, in FIG. 9, the arrow A designates the shield electrode 30 side while the arrow B designates the side on which the electronic components are mounted.

In the following, routing in the flexible substrate (FPC) of the liquid crystal display device according to this embodiment for connecting the GND terminal 51 and the bump electrode PAD to which the GND terminal of the electronic component 21 is electrically and mechanically connected is described with reference to FIGS. 8 and 9.

First, the GND wiring 52 which extends from the GND terminal 51 is connected via the through hole SH6 to the shield electrode 30. Then, in order to avoid the signal wirings 50A, 50D, 50B, and 50E, a GND wiring 52T is connected via a through hole SH7 to the shield electrode 30.

Next, the GND wiring 52T is routed via the through hole SH5 to the surface of the base film 34 which is opposite to the shield electrode 30 side so as to cause the GND wiring 52T to reach the bump electrode PAD to which the GND terminal of the electronic component 21 is electrically and mechanically connected, which is the target of the connection.

As described above, in this embodiment, the shield electrode 30 is used as the GND wiring, and thus, the width of the region in which the components are mounted of the flexible substrate FPC (W2 in FIG. 8) may be made small, and the area occupied by the GND wiring 52 may be made small. Therefore, in this embodiment, downsizing of the flexible substrate FPC and of the region in which the components are mounted may be materialized.

Note that, in the above, a case in which the shield electrode 30 is used as means for connection to the bump electrode PAD to which the GND terminal of the electronic component 21 is electrically and mechanically connected is described, but the present invention may also be applied to a case in which the shield electrode 30 is used to supply the ground voltage GND from one GND wiring to another GND wiring across a plurality of signal wirings.

Further, in the above, an embodiment in which the present invention is applied to the flexible substrate FPC connected to the liquid crystal display panel is described, but the present invention is not limited thereto and may also be applied to, for example, a flexible substrate FPC which is connected to a display panel other than a liquid crystal display panel such as an organic EL display panel.

While there have been described what are at present considered to be certain embodiment of the invention, it will be understood that various modifications may be made thereto, and it is intended that the appended claims cover all such modifications as fall within the true spirit and scope of the invention

What is claimed is:

1. A display device, comprising:
a display panel; and
a flexible substrate connected to the display panel, the flexible substrate having a plurality of electronic components mounted thereon, wherein:
the flexible substrate has a shield electrode on a surface thereof that is opposite to a surface thereof on which the plurality of electronic components are mounted in a region which corresponds to a region in which the plurality of electronic components are mounted;
the shield electrode is supplied with a first reference voltage from outside; and
at least one of the plurality of electronic components is supplied with the first reference voltage via the shield electrode.

2. The display device according to claim 1, wherein 20% or more of the plurality of electronic components is supplied with the first reference voltage via the shield electrode.

3. The display device according to claim 1 or 2, wherein:
the flexible substrate comprises:
a base film;
a plurality of first wiring layers formed on a surface of the base film, which is on the shield electrode side;
an insulating layer formed on the plurality of first wiring layers; and
a plurality of second wiring layers formed on a surface of the base film, which is on the plurality of electronic components side; and
the shield electrode is formed on the insulating layer.

4. The display device according to claim 3, wherein the shield electrode comprises, on a surface thereof, a coating layer including an insulating layer.

5. The display device according to claim 3, wherein the shield electrode is connected via a through hole formed in the insulating layer to a first wiring layer to which the first reference voltage is supplied of the plurality of first wiring layers.

6. The display device according to claim 3, wherein the shield electrode is connected via a through hole formed in the insulating layer and a through hole formed in the base film to a second wiring layer of the plurality of second wiring layers which supplies the first reference voltage to the at least one of the plurality of electronic components.

7. The display device according to claim 1, wherein:
the display device further comprises a first substrate; and
the flexible substrate is electrically and mechanically connected to a terminal portion formed at an end of an arbitrary side of the first substrate.

8. The display device according to claim 7, wherein the plurality of electronic components are formed on a front surface of the flexible substrate seen from above.

9. The display device according to claim 7, wherein:
the display device comprises a liquid crystal display panel; and
the liquid crystal display panel comprises:
the first substrate;
a second substrate; and
liquid crystal sandwiched between the first substrate and the second substrate.

10. A display device, comprising:
a display panel; and
a flexible substrate connected to the display panel, the flexible substrate having a plurality of electronic components mounted thereon, wherein:
the flexible substrate has a shield electrode on a surface thereof that is opposite to a surface thereof on which the plurality of electronic components are mounted in a region which corresponds to a region in which the plurality of electronic components are mounted;
the shield electrode is supplied with a first reference voltage from outside; and
the flexible substrate has a first reference voltage wiring, which is supplied with the first reference voltage via the shield electrode.
